(19) United States
(12) Patent Application Publication
(10) Pub. No.: US 2025/0228078 A1
(43) Pub. Date: Jul. 10, 2025

(54) DISPLAY PANEL AND DISPLAY DEVICE

(71) Applicant: KunShan Go-Visionox Opto-Electronics Co., Ltd, Kunshan (CN)

(72) Inventors: Chuanzhi XU, Kunshan (CN); Zhengfang XIE, Kunshan (CN); Yong WU, Kunshan (CN)

(73) Assignee: KunShan Go-Visionox Opto-Electronics Co., Ltd, Kunshan (CN)

(21) Appl. No.: 19/091,740

(22) Filed: Mar. 26, 2025

Related U.S. Application Data
(63) Continuation of application No. PCT/CN2023/079476, filed on Mar. 3, 2023.

(30) Foreign Application Priority Data
Oct. 19, 2022 (CN) 202211281649.6

(51) Int. Cl. H10K 59/122; H10K 59/173

(52) U.S. Cl. CPC H10K 59/122; H10K 59/173

(57) ABSTRACT

The present application discloses a display panel and a display device. The display panel includes: a substrate; a pixel definition layer disposed on a side of the substrate, the pixel definition layer including first openings in the active area and second openings in the non-active area; and a support layer including first support parts and second support parts, the first support parts being disposed adjacent to the first openings, and the second support parts being disposed adjacent to the second openings. In a thickness direction of the display panel, a difference value between a distance from the top of a side of the first support part facing away from the substrate to the substrate and a distance from the top of a side of the second support part facing away from the substrate to the substrate is less than or equal to a preset difference value.

### CROSS-REFERENCE TO RELATED APPLICATIONS

The application is a continuation of International Application No. PCT/CN2023/079476 filed on Mar. 3, 2023, which claims the priority benefits of Chinese Patent Application No. 202211281649.6 filed on Oct. 19, 2022 and entitled “DISPLAY PANEL AND DISPLAY DEVICE”, both of which are incorporated herein by reference in their entireties.

### FIELD

The present application relates to the field of electronic products, and in particular to a display panel and a display device.

### BACKGROUND ART

With the progress of science and technology, digital display devices such as smart phones and tablet computers are widely used, and display panels are indispensable human-computer communication interfaces of these display devices. For example, an organic light emitting diode (OLED) display panel has the advantages of self-luminescence, energy saving and consumption reduction, being bendable, and good flexibility, etc. Moreover, this display device for realizing display does not need a backlight source and has the characteristics of quick response and good display effect, which has attracted the attention of users and is widely used in end products such as smart phones and tablet computers.

Due to the limitations of film layer structures of the existing display panels, when a display panel drops, film layer structures of an active area and a non-active area of the display panel are prone to non-uniform deformation, causing damages to the display panel.

Therefore, there is an urgent need for a new display panel and display device.

### SUMMARY

Embodiments of the present application provide a display panel and a display device. A difference value between a distance from the top of a first support part to a substrate and a distance from the top of a second support part to the substrate is set to be less than or equal to a preset difference value, and the difference in supporting force between an active area and a non-active area of the display panel is reduced, increasing the strength of a screen of the display panel, ensuring the uniform deformation of the active area and the non-active area of the display panel during a drop strength test or after a drop during actual use of the display panel, and thus reducing the risk of damage.

One embodiment of the present application provides a display panel having an active area and a non-active area adjacent to the active area, the display panel including: a substrate; a pixel definition layer disposed on a side of the substrate, the pixel definition layer including first openings in the active area and second openings in the non-active area; and a support layer including first support parts and second support parts, the first support parts being disposed on a side of the pixel definition layer in the active area facing away from the substrate and being disposed adjacent to the first openings, and the second support parts being disposed on a side of the pixel definition layer in the non-active area facing away from the substrate and being disposed adjacent to the second openings, where in a thickness direction of the display panel, a difference value between a distance from the top of a side of the first support part facing away from the substrate to the substrate and a distance from the top of a side of the second support part facing away from the substrate to the substrate is less than or equal to a preset difference value.

One embodiment of the present application provides a display device, including: a display panel which is a display panel according to any one of the above embodiments.

Compared with the prior art, the display panel provided in the embodiment of the present application includes the substrate, the pixel definition layer and the support layer; the active area includes the first support parts and the first openings adjacent to each other, and the non-active area includes the second support parts and the second openings adjacent to each other; and the difference value between the distance from the top of the first support part to the substrate and the distance from the top of the second support part to the substrate is set to be less than or equal to the preset difference value, and the difference in supporting force between the active area and the non-active area of the display panel is reduced, increasing the strength of a screen of the display panel, ensuring the uniform deformation of the active area and the non-active area of the display panel during a drop strength test or after a drop during actual use of the display panel, and thus reducing the risk of damage.

### BRIEF DESCRIPTION OF THE DRAWINGS

FIG. 1 is a schematic diagram of a structure of a display panel according to an embodiment of the present application;

FIG. 2 is a diagram of a film layer structure, at part B-B in FIG. 1, according to an embodiment;

FIG. 3 is a schematic diagram of arrangements of first support parts and second support parts according to an embodiment of the present application;

FIG. 4 is a diagram of a film layer structure, at part B-B in FIG. 1, according to another embodiment;

FIG. 5 is a diagram of a film layer structure, at part B-B in FIG. 1, according to yet another embodiment.

### DETAILED DESCRIPTION OF EMBODIMENTS

A drop strength test is one of the requirements for display panels. Due to structural limitations of a display panel, support parts may be provided only in an active area but not in a non-active area; in one embodiment, the support parts in the active area may be higher than the support parts in the non-active area. In the drop strength test of a rigid-screen display panel using Frit (glass cement), the display panel will have a difference in supporting force due to the height difference between the support parts in the active area and the non-active area, which results in a difference in deformation between the active area and the non-active area of the display panel after a drop, making the non-active area of the display panel more likely to be broken, and affecting the screen strength uniformity of the display panel.

In order to solve the above problem, in a display panel provided in an embodiment of the present application, a difference value between a distance from the top of a first support part to a substrate and a distance from the top of a second support part to the substrate is set to be less than or equal to a preset difference value, and the difference in supporting force between an active area and a non-active area of the display panel is reduced, thus reducing the risk of damage.

Embodiments of the present application provide a display panel and a display device. Various embodiments of the display panel and the display device will be described below with reference to FIGS. 1 to 5.

Referring to FIGS. 1 to 3, an embodiment of the present application provides a display panel having an active area AA and a non-active area NA adjacent to the active area AA. The display panel includes: a substrate 1; a pixel definition layer 2 disposed on a side of the substrate 1, the pixel definition layer 2 including a plurality of first openings K1 in the active area AA and a plurality of second openings K2 in the non-active area NA; and a support layer 3 including a plurality of first support parts 31 and a plurality of second support parts 32, the first support parts 31 being disposed on a side of the pixel definition layer 2 in the active area AA facing away from the substrate 1 and being disposed adjacent to the first openings K1, and the second support parts 32 being disposed on a side of the pixel definition layer 2 in the non-active area NA facing away from the substrate 1 and being disposed adjacent to the second openings K2. In a thickness direction of the display panel, a difference value between a distance from the top of a side of the first support part 31 facing away from the substrate 1 to the substrate 1 and a distance from the top of a side of the second support part 32 facing away from the substrate 1 to the substrate 1 is less than or equal to a preset difference value.

The display panel provided in the embodiment of the present application includes the substrate 1, the pixel definition layer 2 and the support layer 3; the active area AA includes the first support parts 31 and the first openings K1 adjacent to each other, and the non-active area NA includes the second support parts 32 and the second openings K2 adjacent to each other; and the difference value between the distance from the top of the first support part 31 to the substrate and the distance from the top of the second support part 32 to the substrate is set to be less than or equal to the preset difference value, and the difference in supporting force between the active area AA and the non-active area NA of the display panel is reduced, increasing the strength of a screen of the display panel, ensuring the uniform deformation of the active area AA and the non-active area NA of the display panel during a drop strength test or after a drop during actual use of the display panel, and thus reducing the risk of damage.

The inventors have found through research that providing openings in the pixel definition layer 2 may affect a height of the first support part 31 and/or the second support part 32. Specifically, in the prior art, the pixel definition layer 2 generally has no openings in the non-active area NA. During the preparation of the support layer 3, before curing or baking, the support layer 3 has a certain fluidity, and the height of the second support part 32 formed on the pixel definition layer 2 thus decreases due to the fluidity. Therefore, in this embodiment, the second openings K2 are provided in the pixel definition layer 2 in the non-active area NA to limit a flow range of the second support parts 32, ensuring that the difference value between the distance from the top of the side of the second support part 32 facing away from the substrate 1 to the substrate 1, i.e., a second height, and the distance from the top of the side of the first support part 31 facing away from the substrate 1 to the substrate 1, i.e., a first height, remains within a range of the preset difference value.

It should be noted that in the thickness direction of the display panel, a thickness of the pixel definition layer 2 in the active area AA and a thickness of the pixel definition layer 2 in the non-active area NA may be equal or unequal, and a user may adjust the difference value between the distance from the top of the first support part 31 to the substrate 1 and the distance from the top of the second support part 32 to the substrate 1 by adjusting the heights of the first support part 31 and the second support part 32, i.e., a height from the top of the first support part 31 to the pixel definition layer 2 and a height from the second support part 32 to the pixel definition layer 2. In one embodiment, since the pixel definition layer 2 in the active area AA and the pixel definition layer 2 in the non-active area NA are usually formed by the same process, the thickness of the pixel definition layer 2 in the active area AA and the thickness of the pixel definition layer 2 in the non-active area NA are also usually equal.

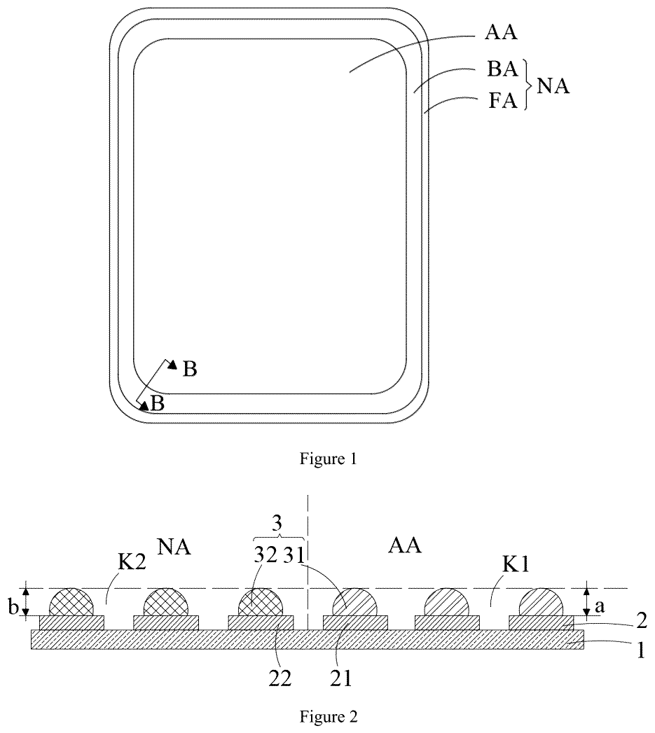

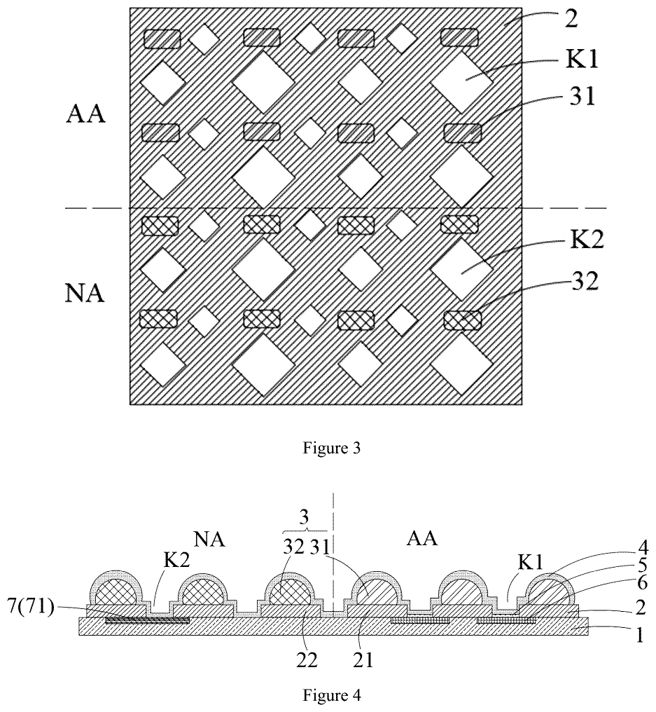

As shown in FIG. 2, when the thickness of the pixel definition layer 2 in the active area AA is equal to the thickness of the pixel definition layer 2 in the non-active area NA, the height of the first support part 31 itself is a, the height of the second support part 32 itself is b, the absolute value of a difference value between a and b is the preset difference value, the specific value of the preset difference value may be selected depending on the height of the first support part 31. For example, the preset difference value may be less than or equal to 10% of the height of the first support part 31 to ensure that the height difference between the first support part 31 and the second support part 32 is not excessively large, thus improving the screen strength uniformity in the active area AA and the non-active area NA of the display panel.

In this embodiment, the support layer 3 and the pixel definition layer 2 may be made of the same material, in order to reduce production costs. In one embodiment, the material of the support layer 3 and the pixel definition layer 2 includes an organic resin material. For example, the support layer 3 and the pixel definition layer 2 may be made of hexamethyldisiloxane, epoxy resin, or polyimide (PI), etc.

The first openings K1 and the second openings K2 of the pixel definition layer 2 may be formed together by the same process, in order to reduce production costs. For example, the pixel definition layer 2 may be patterned by means of photolithography or laser etching, etc., to form the first openings K1 and the second openings K2. The first support part 31 and the second support part 32 of the support layer 3 may also be formed together by the same process, thus reducing costs and also enabling the first support part 31 and the second support part 32 to be placed in the same preparation environment, which is more conducive to achieving the same height of the first support part 31 and the second support part 32. In one embodiment, the first support part 31 and the second support part 32 may also be formed by means of photolithography or laser etching, etc. For example, the first support part 31 and the second support part 32 may be formed by evaporation with the same mask, which is not limited specifically.

In one embodiment, the non-active area NA includes a barrier area BA and an encapsulation area FA. The second support part 32 is disposed in the barrier area BA, and an encapsulation adhesive is provided in the encapsulation area FA. The encapsulation adhesive is disposed on a side of the second support part 32 facing away from the active area AA to encapsulate a bezel part of the display panel. The encapsulation adhesive may be specifically made of a material such as Frit (glass cement).

In one embodiment, at least two rows of second support parts 32 are provided in a direction from the active area AA to the non-active area NA, to ensure that the second support parts 32 have sufficient supporting force.

In some embodiments, in the thickness direction of the display panel, a ratio of a height of the first support part 31 to a height of the second support part 32 ranges from 0.9 to 1.1. It should be understood that the heights of the first support part 31 and the second support part 32 specifically refer to the distance from the top of the first support part 31 to the pixel definition layer 2 and the distance from the top of the second support part 32 to the pixel definition layer 2 in the thickness direction of the display panel; the smaller height difference between the first support part 31 and the second support part 32 leads to the smaller difference in supporting force corresponding to the first support part 31 and the second support part 32. Considering the influence of factors such as process errors and the fluidity of the first support part 31 and the second support part 32, the ratio of the height of the first support part 31 to the height of the second support part 32 ranges from 0.9 to 1.1. For example, when the height of the first support part 31 is 20 μm, the height of the second support part 32 ranges from 18 to 22 μm. In one embodiment, the height of the first support part 31 is equal to the height of the second support part 32, that is, when the height of the first support part 31 is 20 μm, the height of the second support part 32 may also be 20 μm. Of course, the above-mentioned specific height values of the first support part 31 and the second support part 32 only illustrate a height relationship between the first support part 31 and the second support part 32, and do not represent the actual heights of the first support part 31 and the second support part 32.

In one embodiment, in order to enable the distance from the top of the first support part 31 to the substrate 1 to be equal to the distance from the top of the second support part 32 to the substrate 1, the thickness of the pixel definition layer 2 in the active area AA may be equal to the thickness of the pixel definition layer 2 in the non-active area NA, and the pixel definition layer 2 in the active area AA and the pixel definition layer 2 in the non-active area NA are formed by the same process at one time, and the distance from the top of the first support part 31 to the substrate 1 is equal to the distance from the top of the second support part 32 to the substrate 1 by controlling and adjusting the heights of the first support part 31 and the second support part 32 only during preparation, thus reducing the process difficulty.

Referring to FIG. 2, in some embodiments, the pixel definition layer 2 includes first pixel definition parts 21 for carrying the first support parts 31 and second pixel definition parts 22 for carrying the second support parts 32, a ratio of a distance between two adjacent first pixel definition parts 21 to a distance between two adjacent second pixel definition parts 22 ranging from 0.9 to 1.1.

It should be understood that the first support parts 31 and the second support parts 32 are disposed on the first pixel definition parts 21 and the second pixel definition parts 22, respectively. Therefore, the distance between two adjacent first pixel definition parts 21 and the distance between two adjacent second pixel definition parts 22 affect the arrangement density of the corresponding first support parts 31 and second support parts 32 and the specific size of the corresponding first openings K1 and second openings K2. The arrangement density of the first support parts 31 and the second support parts 32 and the specific size of the corresponding first openings K1 and the second openings K2 both affect the deformation of the active area AA and the non-active area NA of the display panel during a drop strength test or after a drop during actual use of the first support parts 31 and the second support parts 32. Accordingly, in this embodiment, the difference in arrangement of the first pixel definition parts 21 in the active area AA and the second pixel definition parts 22 in the non-active area NA of the display panel may be reduced by limiting the ratio of the distance between two adjacent first pixel definition parts 21 to the distance between two second pixel definition parts 22 to be within the range of 0.9 to 1.1.

In one embodiment, the distance between two adjacent first pixel definition parts 21 is equal to the distance between two adjacent second pixel definition parts 22, and the first pixel definition parts 21 and the second pixel definition parts 22 provide the same supporting effect for the first support parts 31 and the second support parts 32, respectively. In one embodiment, the distance between two adjacent first pixel definition parts 21 ranges from 10 to 50 μm, and the distance between two adjacent second pixel definition parts 22 also ranges from 10 to 50 μm.

In some embodiments, in the thickness direction of the display panel, a ratio of a projection area of the first pixel definition part 21 on the substrate 1 to a projection area of the second pixel definition part 22 on the substrate 1 ranges from 0.9 to 1.1.

The size of the first pixel definition part 21 and the second pixel definition part 22 affects the flow of the first support part 31 and the second support part 32, thus affecting the heights of the first support part 31 and the second support part 32, as tested experimentally by the inventors. In one embodiment, the larger the first pixel definition part 21 is, correspondingly, the smaller the first opening K1 is when the distance between two adjacent first pixel definition parts 21 is fixed, and the smaller the height of the first support part 31 finally formed is. Similarly, the larger the second pixel definition part 22, correspondingly, the smaller the second opening K2 is when the distance between adjacent two second pixel definition parts 22 is fixed, and the smaller the height of the second support part 32 finally formed is. Therefore, in this embodiment, the flow effect of the first support part 31 and the second support part 32 can be correspondingly limited by limiting the projection area of the first pixel definition part 21 on the substrate 1 and the projection area of the second pixel definition part 22 on the substrate 1, and the height difference between the first support part 31 and the second support part 32 can meet the requirements.

In one embodiment, the projection area of the first pixel definition part 21 on the substrate 1 is equal to the projection area of the second pixel definition part 22 on the substrate 1. It should be understood that a relative relationship between the projection area of the first pixel definition part 21 on the substrate 1 and the projection area of the second pixel definition part 22 on the substrate 1 corresponds to a height relationship between the first support part 31 and the second support part 32. Therefore, when the projection areas of the first pixel definition part 21 and the second pixel definition part 22 are equal, it is more conducive to meeting the requirement for the first support part 31 and the second support part 32 to have equal heights.

In order to further limit the flow of the second support part 32 and thus avoid the problem of the second support part 32 being too short relative to the first support part 31, in some embodiments, a minimum distance from the second support part 32 to an edge of the second pixel definition part 22 corresponding to the second support part 32 is 0 to 5 μm.

In this embodiment, as tested experimentally by the inventors, the greater minimum distance from the second support part 32 to the edge of the second pixel definition part 22 corresponding to the second support part 32 leads to the greater deformation of the second support part 32 due to the fluidity, and the smaller height thereof. Therefore, it is necessary to limit the minimum distance from the second support part 32 to the edge of the second pixel definition part 22 corresponding to the second support part 32 not to be excessively large. In one embodiment, it is also necessary to prevent the second support part 32 from directly flowing into the second opening K2. In one embodiment, the minimum distance from the second support part 32 to the edge of the second pixel definition part 22 corresponding to the second support part 32 is 5 μm.

Referring to FIG. 3, in some embodiments, an arrangement form of the first support parts 31 in the active area AA is the same as an arrangement form of the second support parts 32 in the non-active area NA.

It should be noted that the arrangement form in this embodiment includes, but is not limited to, factors such as the arrangement position, specific shape, and size of the first support part 31 or the second support part 32. The arrangement form of the first support parts 31 being the same as the arrangement form of the second support parts 32 facilitates the preparation of the first support parts 31 and the second support parts 32 of the same height, and also enables the first support parts 31 and the second support parts 32 to provide the same supporting force, thus increasing the strength of the screen of the display panel, ensuring the uniform deformation of the active area AA and the non-active area NA of the display panel during a drop strength test or after a drop during actual use of the display panel, and thus reducing the risk of damage.

In one embodiment, an arrangement form of the first openings K1 in the active area AA is the same as an arrangement form of the second openings K2 in the non-active area NA, which further improves the structure consistency of the active area AA and the non-active area NA of the display panel, and also ensures that the first openings K1 and the second openings K2 have the same blocking effect for the first support parts 31 and the second support parts 32, respectively and that the height difference between the second support parts 32 and the first support parts 31 can remain within the range of the preset difference value.

Referring to FIG. 4, in some embodiments, considering some signal traces usually provided in the non-active area NA, it is necessary to provide the pixel definition layer 2 specifically according to different signals transmitted by the signal traces. In some embodiments, the display panel further includes a signal line layer 7. The signal line layer 7 is located in the non-active area NA and is located between the pixel definition layer 2 and the substrate 1, the signal line layer 7 includes low-level voltage signal lines 71, and the second openings K2 expose at least a portion of the low-level voltage signal line 71.

It should be noted that since the low-level voltage signal line 71, i.e., a VSS signal line, is usually connected to a cathode layer 4 to provide a low-level voltage signal for the cathode layer 4, and since the cathode layer 4 is deposited over the entire surface and is provided in both the active area AA and the non-active area NA, in this embodiment, the second opening K2 exposing at least a portion of the low-level voltage signal line 71 facilitates the connection between the low-level voltage signal line 71 and the cathode layer 4.

In one embodiment, the display panel further includes a cathode layer 4. The cathode layer 4 covers a side of the pixel definition layer 2 facing away from the substrate 1 and is partially located within the first openings K1 and the second openings K2, and the low-level voltage signal line 71 is electrically connected to the cathode layer 4.

In one embodiment, the active area AA further includes an anode layer 6 and a light-emitting layer 5 stacked in the thickness direction of the display panel. The cathode layer 4 at least partially covers a side of the light-emitting layer 5 facing away from the substrate 1, and the low-level voltage signal line 71 may be arranged in the same layer as the anode layer 6, that is, the low-level voltage signal line 71 and the anode layer 6 may be formed by the same process and made of the same material, thus reducing the production costs.

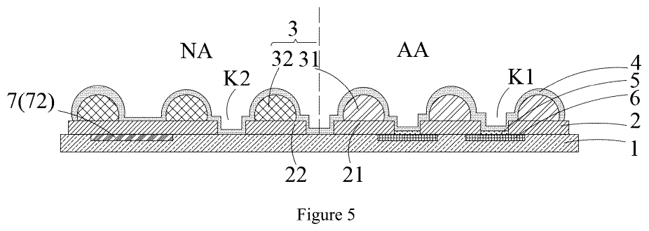

Referring to FIG. 5, in on embodiment, the signal line layer 7 includes high-level voltage signal lines 72. Since the high-level voltage signal line 72 and the cathode layer 4 are not connected to each other, which have different signals, the high-level voltage signal line 72 needs to be separated from the cathode layer 4 by the pixel definition layer 2, that is, the second openings K2 will not expose the high-level voltage signal line 72, thus avoiding problems such as short circuits and signal crosstalk.

In this embodiment, the cathode layer 4 is generally made of a material having a low work function, which facilitates electron injection and may also reduce the heat generated during operation to prolong service life of OLED devices. The material of the cathode layer 4 may be one of metal materials such as silver (Ag), aluminum (Al), lithium (Li), magnesium (Mg), ytterbium (Yb), calcium (Ca), or indium (In), and may also be an alloy of the foregoing metal materials, such as a magnesium-silver alloy (Mg/Ag), and a lithium-aluminum alloy (Li/Al), which is not limited in this embodiment.

The anode layer 6 is generally made of a material having a high work function, which is conducive to improving the hole injection efficie-ncy. The materials of the anode layer 6 and the signal line layer 7 may be gold (Au), platinum (Pt), titanium (Ti), silver (Ag), indium tin oxide (ITO), zinc tin oxide (IZO), or transparent conductive polymers (such as polyaniline), etc.

The present application further provides a display device. The display device includes a display panel which is a display panel in any one of the above embodiments.

Accordingly, the display device provided in the embodiment of the present application has the effect of the embodiment of the display panel in any one of the above embodiments, and the structure and the explanation of terms that are the same as or corresponding to the above embodiments will not be repeated herein.

The display device provided in the embodiment of the present application may be applied to a smart phone, or any electronic product with a display function, including, but not limited to: a TV set, a notebook computer, a desktop monitor, a tablet computer, a digital camera, a smart bracelet, smart glasses, a vehicle-mounted display, a medical apparatus, an industrial control apparatus, a touch interaction terminal, etc., which is not specifically limited in the embodiments of the present application.

1. A display panel having an active area and a non-active area adjacent to the active area, the display panel comprising:
a substrate;
a pixel definition layer disposed on a side of the substrate, the pixel definition layer comprising a plurality of first openings in the active area and a plurality of second openings in the non-active area; and
a support layer comprising a plurality of first support parts and a plurality of second support parts, the first support parts being disposed on a side of the pixel definition layer in the active area facing away from the substrate and being disposed adjacent to the first openings, and the second support parts being disposed on a side of the pixel definition layer in the non-active area facing away from the substrate and being disposed adjacent to the second openings, wherein in a thickness direction of the display panel, a difference value between a distance from the top of a side of the first support part facing away from the substrate to the substrate and a distance from the top of a side of the second support part facing away from the substrate to the substrate is less than or equal to a preset difference value.

2. The display panel according to claim 1, wherein in the thickness direction of the display panel, a ratio of a height of the first support part to a height of the second support part ranges from 0.9 to 1.1.

3. The display panel according to claim 2, wherein the height of the first support part is equal to the height of the second support part.

4. The display panel according to claim 1, wherein in the thickness direction of the display panel, the pixel definition layer in the active area has a thickness equal to a thickness of the pixel definition layer in the non-active area.

5. The display panel according to claim 1, wherein the pixel definition layer comprises a plurality of first pixel definition parts for carrying the first support parts and a plurality of second pixel definition parts for carrying the second support parts, a ratio of a distance between two adjacent first pixel definition parts to a distance between two adjacent second pixel definition parts ranging from 0.9 to 1.1.

6. The display panel according to claim 5, wherein the distance between two adjacent first pixel definition parts is equal to the distance between two adjacent second pixel definition parts.

7. The display panel according to claim 5, wherein the distance between two adjacent first pixel definition parts is 10 μm-50 μm.

8. The display panel according to claim 5, wherein the distance between two adjacent second pixel definition parts is 10 μm-50 μm.

9. The display panel according to claim 5, wherein in the thickness direction of the display panel, a ratio of a projection area of the first pixel definition part on the substrate to a projection area of the second pixel definition part on the substrate ranges from 0.9 to 1.1.

10. The display panel according to claim 9, wherein the projection area of the first pixel definition part on the substrate is equal to the projection area of the second pixel definition part on the substrate.

11. The display panel according to claim 5, wherein a minimum distance from the second support part to an edge of the second pixel definition part corresponding to the second support part is 0 to 5 μm.

12. The display panel according to claim 1, wherein an arrangement form of the first support parts in the active area is the same as an arrangement form of the second support parts in the non-active area.

13. The display panel according to claim 1, further comprising a signal line layer, wherein the signal line layer is located in the non-active area and is located between the pixel definition layer and the substrate, the signal line layer comprises a plurality of low-level voltage signal lines, and the second openings expose at least a portion of the low-level voltage signal line.

14. The display panel according to claim 13, further comprising a cathode layer, wherein the cathode layer covers a side of the pixel definition layer facing away from the substrate and is partially located within the first openings and the second openings, and the low-level voltage signal line is electrically connected to the cathode layer.

15. The display panel according to claim 13, further comprising an anode layer, wherein the low-level voltage signal line is arranged in the same layer as the anode layer.

16. The display panel according to claim 1, wherein the support layer and the pixel definition layer are made of the same material.

17. The display panel according to claim 16, wherein the material of the support layer and the pixel definition layer comprises an organic resin material.

18. The display panel according to claim 1, wherein the preset difference value is less than or equal to 10% of the height of the first support part.

19. The display panel according to claim 13, wherein the signal line layer comprises a plurality of high-level voltage signal lines, the high-level voltage signal line is separated from a cathode layer by the pixel definition layer.

20. A display device, comprising:
a display panel having an active area and a non-active area adjacent to the active area, the display panel comprising:
a substrate;
a pixel definition layer disposed on a side of the substrate, the pixel definition layer comprising a plurality of first openings in the active area and a plurality of second openings in the non-active area; and
a support layer comprising a plurality of first support parts and a plurality of second support parts, the first support parts being disposed on a side of the pixel definition layer in the active area facing away from the substrate and being disposed adjacent to the first openings, and the second support parts being disposed on a side of the pixel definition layer in the non-active area facing away from the substrate and being disposed adjacent to the second openings, wherein
in a thickness direction of the display panel, a difference value between a distance from the top of a side of the first support part facing away from the substrate to the substrate and a distance from the top of a side of the second support part facing away from the substrate to the substrate is less than or equal to a preset difference value.
